(19) United States
(12) Patent Application Publication
(10) Pub. No.: US 2012/0199199 A1
(43) Pub. Date: Aug. 9, 2012

(54) EDGE SEALANT COMPOSITION WITH REACTIVE OR UNSATURATED POLYOLEFINS

(75) Inventors: James Wood, Jackson, MI (US); Rahul Rasal, Saint Paul, MN (US); Kathleen Lamb, Jackson, MI (US); Harald Becker, Stelzenberg (DE); Heike Brucher, Rathsweiler (DE); Norbert Schott, Zweibrucken (DE)

(73) Assignee: ADCO PRODUCTS, INC., Michigan Center, MI (US)

(21) Appl. No.: 13/501,927

(22) PCT Filed: Oct. 14, 2010
(86) PCT No.: PCT/US2010/052718

§ 371 Date: Apr. 13, 2012

Related U.S. Application Data
(60) Provisional application No. 61/251,542, filed on Oct. 14, 2009.

(51) Int. Cl. H01L 31/0203; C08K 5/17; C08K 5/07; C08K 5/51; C08K 5/3475; C08K 5/13; C08K 5/36

(52) U.S. Cl. 136/259; 524/323; 524/236; 524/392; 524/136; 524/91; 524/359

(57) ABSTRACT

A solar module includes a photovoltaic device that has an edge seal. The sealant composition of the edge seal includes an unsaturated or reactive polyolefin, an olefinic polymer, a silane modified polyolefin, inert fillers, a water scavenger or desiccant, an antioxidant, and a UV stabilizer. These components are balanced to produce a sealant having desirable sealing characteristics, high weatherability, desired rheology, low conductivity, and good thermal stability.

### CROSS-REFERENCE TO RELATED PATENT APPLICATIONS

This patent application claims the benefit of U.S. Provisional Patent Application No. 61/251,542, filed on Oct. 14, 2009, and is a continuation-in-part of co-pending U.S. patent application Ser. No. 12/679,250, filed on Mar. 19, 2010, which claims the benefit of International Application No. PCT/DE/2008/001564, filed on Sep. 22, 2008, which claims the benefit of German priority document DE/10 2007 045 104.2, filed on Sep. 20, 2007. The contents of the above applications are incorporated herein by reference in their entirety.

### FIELD

The present invention relates to edge sealant compositions having reactive or unsaturated polyolefins, and more particularly, edge sealants having reactive or unsaturated polyolefins that can be used in solar modules.

### BACKGROUND

Photovoltaic solar panels or modules generally include a photovoltaic device that is laminated and/or sandwiched between a plurality of layers. The majority of photovoltaic devices are rigid wafer-based crystalline silicon cells or thin film modules having cadmium telluride (Cd—Te), amorphous silicon, or copper-indium-diselenide (CuInSe₂) deposited on a substrate. The thin film solar modules may be either rigid or flexible. Flexible thin film cells and modules are created by depositing the photoactive layer and any other necessary substance on a flexible substrate. Photovoltaic devices are connected electrically to one another and to other solar panels or modules to form an integrated system.

The efficiency of photovoltaic solar panels is lessened by intrusion of moisture. One effective method of lessening this transfer of moisture from the environment to the interior, moisture sensitive portion of the solar module is to use edge sealants. These edge sealants have the property of having a low rate of moisture transmission, MVT.

Edge sealants in solar modules are exposed to high temperatures, for example, in the lamination step during construction of the solar module. Accordingly, it is desirable that these edge sealants have thermal stability. Most of edge sealants are polyolefinic in nature. Therefore, the dominant degradation mechanism during high temperature exposure is random chain scission. Once these free radicals are formed (as a consequence of random chain scission), the degradation propagates. In addition to this, the applications where sealants will be exposed to thermal/photo initiators (such as encapsulants, for example, EVA, in solar modules), those initiators would tend to degrade sealants. This may have detrimental ramifications (e.g. strength loss, loss of adhesion to glass) with respect to sealants' bulk and surface properties. Accordingly, there is room in the art for an edge sealant that exhibits good thermal stability in high temperature conditions and resistance to degradation (long term stability in the field) upon exposure to initiators (encapsulant) in solar modules.

### SUMMARY

A solar module includes a photovoltaic device that has an edge seal. The sealant composition of the edge seal includes an unsaturated or reactive polyolefin, an olefinic polymer, a silane modified polyolefin, inert fillers, a water scavenger or desiccant, an antioxidant, and a UV stabilizer. These components are balanced to produce a sealant having desirable sealing characteristics, high weatherability, desired rheology, low conductivity, and good thermal stability.

Further features, advantages, and areas of applicability will become apparent from the description provided herein. It should be understood that the description and specific examples are intended for purposes of illustration only and are not intended to limit the scope of the present disclosure.

### DRAWINGS

The drawings described herein are for illustration purposes only and are not intended to limit the scope of the present disclosure in any way. The components in the figures are not necessarily to scale, emphasis instead being placed upon illustrating the principles of the invention. In the drawings:

FIG. 1 is a top view of an embodiment of a solar module having a border seal composition according to the principles of the present invention;

FIG. 2 is a cross-sectional view of a portion of an embodiment of a solar module having a border seal composition according to the present invention;

FIG. 3 is a bar graph showing weight loss upon seven days of incubation in 180° C. air circulated ovens for unsaturated or reactive polymers; and

FIG. 4 is a bar graph showing weight loss upon seven days of incubation in 180° C. air circulated ovens for unreactive polyisobutenes (PIBs).

### DETAILED DESCRIPTION

The following description is merely exemplary in nature and is not intended to limit the present disclosure, application, or uses.

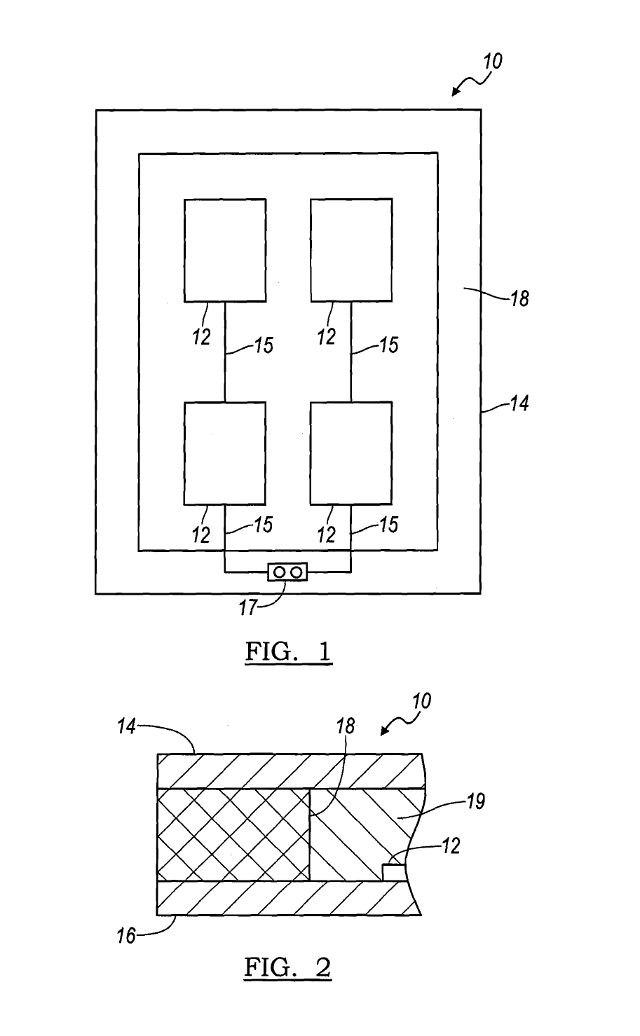

With reference to FIGS. 1 and 2, an exemplary solar module employing a sealant composition according to the principles of the present invention is generally indicated by reference number 10. The solar module 10 may take various forms without departing from the scope of the present invention and generally includes at least one photovoltaic cell 12 located within a chamber 13 defined by a first substrate 14 and a second substrate 16. While a plurality of photovoltaic cells 12 are illustrated, it should be appreciated that any number of photovoltaic cells 12 may be employed.

The photovoltaic cell 12 is operable to generate an electrical current from sunlight striking the photovoltaic cell 12. Accordingly, the photovoltaic cell 12 may take various forms without departing from the scope of the present invention. For example, the photovoltaic cell 12 may be a thin film cell with a layer of cadmium telluride (Cd—Te), amorphous silicon, or copper-indium-diselenide (CuInSe₂). Alternatively, the photovoltaic cell 12 may be a crystalline silicon wafer embedded in a laminating film or gallium arsenide deposited on germanium or another substrate. Other types of photovoltaic devices 12 that may be employed include organic semiconductor cells having conjugate polymers as well as dye-sensitized metal oxides including wet metal oxides and solid metal oxides. The photovoltaic device 12 may be either rigid or flexible. The photovoltaic cells 12 are linked either in series or in parallel or combinations thereof. The current produced by the photovoltaic devices 12 are communicated via bus bars or other conductive materials or layers to wires or lead lines 15 that exit the solar module 10. The lead lines 15 communicate with a junction box 17 in order to distribute the electrical current generated by the solar module 10 to a power circuit.

The first substrate 14, or front panel, is formed from a material operable to allow wavelengths of sunlight to pass therethrough. For example, the first substrate 14 is glass or a plastic film such as polyvinylflouride. The second substrate 16, or back panel, is selected to provide additional strength to the solar module 10. For example, the second substrate 16 is a plastic such as fluorinated ethylene-propylene copolymer (FEP), poly(ethylene-co-tetrafluoroethylene) (ETFE), polyvinylidene fluoride (PVDF), polyvinyl fluoride (PVF), poly(tetrafluoroethylene) (PTFE) and combinations of these with other polymeric materials.

The photovoltaic cells 12 are encapsulated by a laminate layer 19 that is preferably cross-linkable ethyl vinyl acetate (EVA). However, it should be appreciated that other laminates or thermoplastic encapsulants may be employed without departing from the scope of the present invention. The laminate layer 19 is used to partially encapsulate the photovoltaic device 12 to protect the photovoltaic device 12 from contamination, mechanical stress, and from the environment.

A border or edge seal 18 is located near an edge of the solar module 10 between the first substrate 14 and the second substrate 16. The border seal 18 may have various widths. In addition, a second border seal (not shown) may also be included. The second border seal may be comprised of, for example, for example, a silicone, an MS polymer, a Silanated Polyurethane, a butyl, or a polysulfide. The border seal 18 is operable to seal the laminate layer 19 and photovoltaic devices 12. The border seal 18 must have sufficient weatherability to withstand exposure to outside environments including prolonged ultra-violet radiation exposure, have low moisture and vapor transmission (MVT), and have low conductivity. The border seal 20 is comprised of a sealant composition having the unique characteristics of high weatherability with low conductivity and MVT, as will be described in greater detail below, as well as good thermal stability and oxidative stability.

The sealant composition of the border seal 18 includes an unsaturated or reactive polyolefin, an olefinic polymer, a silane modified polyolefin, inert fillers, a water scavenger, an antioxidant, and a UV stabilizer. These components are balanced to produce a sealant having desirable sealing characteristics, high weatherability, desired rheology, low conductivity, and good thermal stability.

In some embodiments of the sealant, the unsaturated or reactive polyolefins are selected from the group EPDMs, polyolefin acrylates, and halobutyls. The olefinic polymers are selected from the group comprising polyisobutylene, polybutene, butyl rubber (polyisobutylene-isoprene), styrene block copolymers, especially SBS, SIS, SEBS, SEPS, SIBS, SPIBS, also in modified form, and amorphous copolymers and/or terpolymers of α-olefins (APAO).

The scope of the invention provides for the modified polymer to be selected from the group comprising polyisobutylene, polybutene, butyl rubber (polyisobutylene-isoprene), styrene block copolymers, especially SBS, SIS, SEBS, SEPS, SIBS, SPIBS, also in modified form, and amorphous copolymers and/or terpolymers of α-olefins (APAO), the polymer being modified with at least one group of formula (1) which is a terminal group or is distributed statistically within the chain

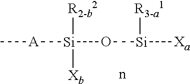

where -A- is

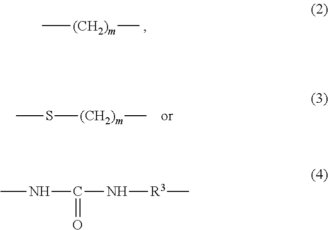

and R¹ and R² are the same or different and are an alkyl group having 1 to 20 carbon atoms, an aryl group having 6 to 20 carbon atoms or an aralkyl group having 7 to 20 carbon atoms,
X is a hydroxyl group or a hydrolyzable group,
a is 0, 1, 2 or 3 and b is 0, 1 or 2, the sum of a and b being greater than or equal to 1, and where n is a whole number between 0 and 18, m is a whole number between 0 and 4 and R³ is

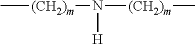

It is also within the scope of the invention for the fillers to be selected from the group comprising ground and precipitated chalks, silicates, lime, silicon oxides and carbon blacks.

In this connection, the invention also provides for the chalks to be surface-treated.

However, it is also possible to use non-surface-treated chalks.

The invention furthermore provides for the silicates to be selected from the group comprising talc, kaolin, mica, silicon oxides, silicas and calcium or magnesium silicates.

It is also with the scope of the invention for the desiccants or water scavengers to be selected from molecular sieves (zeolites) of types 3A to 10A.

Of course, other substances that bond water chemically or physically may also be used.

It is possible to formulate the sealing compound either as a one-part sealing compound or as a two-part sealing compound. In the case of a one-part sealing compound, all the components are mixed together during the production process. In the case of a two-part sealing compound, some components form one part and the other components form the other part. The two parts of the compound are then mixed together immediately prior to application.

The invention also provides for the aging resistors to be selected from the group comprising sterically hindered phenols, thioethers, mercapto compounds, phosphorus esters, benzotriazoles, benzophenones, HALS and antiozonants.

In various implementations, the sealing compound can be employed for fabricating insulating glass for windows, conservatories, structural and roof glazing, for glazing in land-bound vehicles, watercraft and aircraft, and for manufacturing solar modules, including thermoelectric solar modules. The sealing compound with unsaturated or reactive polyolefin in addition to a silane modified polymer is designed to cure during lamination to provide additional structural strength.

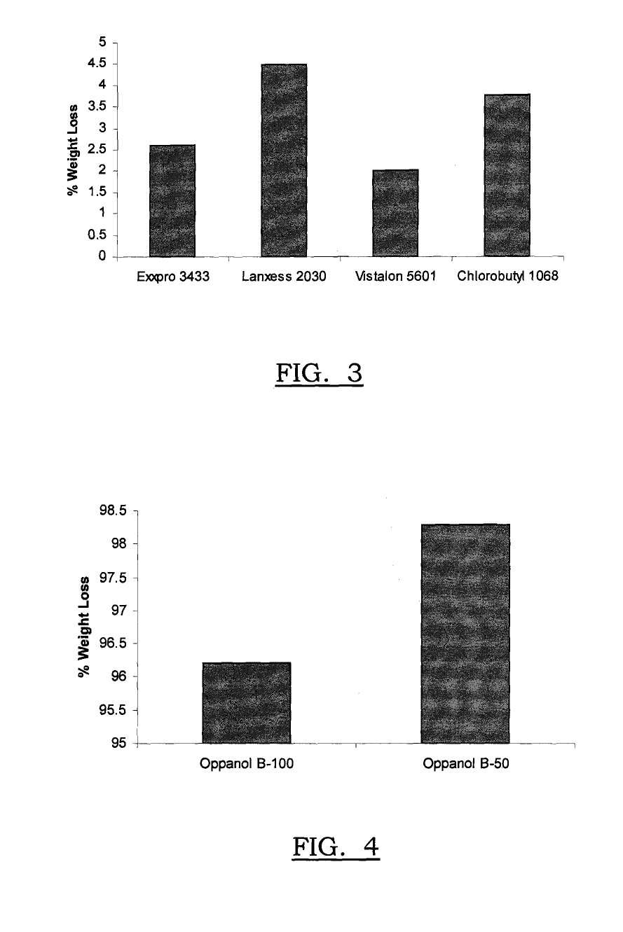

As a proof-of-concept, the following unsaturated or reactive polyolefins were tested: Exxpro 3433 (Exxon), Lanxess bromobutyl 2030 (Lanxess), EPDM (Vistalon 5601) (Exxon), and Exxon chlorobutyl 1068. All samples were incubated in 180° C. air circulated ovens for 7 days and weighed to calculate the weight loss. The weight loss is proportional to the extent of thermal degradation (converse of thermal stability). Exposure to 180° C. air circulated ovens for 7 days was chosen as an extreme condition to investigate the thermal stability of polymers. Butyls would tend to undergo an extensive thermal degradation under these extreme conditions, resulting in significant weight loss. The predominant degradation mechanism under these conditions is more likely the random chain scission, until the point that small enough molecules are formed that will be carried away by air, resulting in weight loss. Also, oxygen will accelerate the rate of the thermal degradation, since once a radical is formed by random chain scission, oxygen molecules would react with it to form alkoxy and peroxy radicals. The reactivity of unsaturated rubbers tends to use these free radicals and stop further degradation. In many cases, it has been observed that the combination of unsaturation and radicals leads to molecular weight build-up and/or cross linking, further increasing the strength. It can be clearly seen from FIG. 3 that the chosen reactive or unsaturated polyolefins showed minimal weight loss (less that 5%) upon 7 days air circulated oven exposure at 180° C. Unreactive polyolefins (Oppanol B-100 and B-50 from BASF) showed (see FIG. 4) more than 95% weight loss upon exposure to similar conditions.

The reactive and/or unsaturation sites were observed to react with free radicals formed upon high temperature exposure leading to minimal degradation (if any) and improved thermal stability. The edge seal exhibits low MVTR and can cross-link upon reaction with free radicals, where the free radicals may be the result of thermal or thermo-oxidative degradation or reaction with peroxides contained in encapsulants in the solar module. In addition, the edge sealant exhibits less than 10% weight loss upon aging in an air circulated oven at 180 degree C. for 7 days, an accelerated aging test as a measure of thermal and thermo-oxidative stability. More preferably, the edge sealant exhibits less than 7.5% weight loss upon aging in an air circulated oven at 180 degrees C. for 7 days.

Of particular interest are the EPDM polymers, which contain an unsaturated polymeric backbone comprised of monomers of ethylene and propylene with a small but significant amount of at least one non-conjugated diene, such as norbornadiene, dicyclopentadiene, and/or 1,5-hexadiene. The significance is that with the various EPDM polymers, a preferential duality exists: While the backbone is fully saturated and thereby highly stable and non-reactive toward most moieties including peroxides and other oxidants, the presence of occasional double bonds in the side chains allows for crosslinking, and should these side chain bonds cleave, the backbone remains intact.

Note that in FIG. 1, while all formations containing all of the listed polymers gave impressively low weight loss results, the formulation containing the EPDM (Vistalon) gave the lowest weight loss result. Theoretically, in environments more challenging, the EPDM containing formulation would be expected to withstand the harsher environment better, differentiating itself from the others.

EPDM also affords reactivity and saturated backbone without inclusion of halogens such as chlorine or bromine. Offgassing of hydrochroric and hydrobromic acids is not possible with EPDM.

In order that the invention may be more readily understood, reference is made to the following examples which are intended to illustrate the principles of the invention, but not limit the scope thereof:

### EXAMPLE 1

| Material | Wt % |
|---|---|
| Unsaturated or reactive polyolefin | 10 to 80 |
| Olefinic polymer | 5 to 50 |
| Silane modified polyolefins | 5 to 30 |
| Inert fillers | 10 to 60 |
| Water scavenger | 2.5 to 25 |
| Aging Resistors | 0 to 3 |

### EXAMPLE 2

| Material | Wt % |
|---|---|
| Unsaturated or reactive polyolefin | 10 to 60 |
| Olefinic polymer | 5 to 40 |
| Silane modified polyolefins | 5 to 25 |
| Inert fillers | 10 to 60 |
| Water scavenger | 2.5 to 25 |
| Aging Resistors | 0 to 2 |

### EXAMPLE 3

| Material | Wt % |
|---|---|
| Unsaturated or reactive polyolefin | 30 to 60 |
| Olefinic polymer | 10 to 40 |
| Silane modified polyolefins | 10 to 25 |
| Inert fillers | 30 to 60 |
| Water scavenger | 2.5 to 25 |
| Aging Resistors | 0 to 2 |

where for each of the examples the components are:

Unsaturate reactive polyolefins such as EPDMs, polyolefin acrylates, and halobutyls of Molecular weight Mn 100-100,000 Da preferabaly 100-500,000 Da

Olefinic polymer: Polyethylene, polypropylene, polybutene, polyisobutene, butyl rubber (polyisobutene-isoprene) styrene block copolymers (in modified form as well): For all olefinic polymers Mol wt (Mn 100-1,000, 000 Da, preferabaly 100-300,000 Da)

Silanes: DFDA-5451NT (silane grafted PE from Dow Chemical), DFDA-5481 NT (moisture curing catalyst from Dow Chemical), amorphous poly alpha olefins (such as and not restricted to Vestoplast 206, Vestoplast 2412), alkoxy silanes, amino silanes

Inert fillers: ground and precipitated chalks, silicates, silicon oxides, and Carbon black, CaCO₃, Ca(OH)₂, titanium dioxide Silicates to be selected from the group comprising talc, kaolin, mica, silicon oxide, silicas, and calcium or magnesium silicates

Water scavenger such as CaO or desiccant such as molecular sieves, silica gel, and calcium sulfate

Aging Resistors: Hindered phenols, hindered amines, thioethers, mercapto compounds, phosphorous esters benzotriazoles, benzophenones, and antiozonants

The description of the invention is merely exemplary in nature and variations that do not depart from the gist of the invention are intended to be within the scope of the invention. Such variations are not to be regarded as a departure from the spirit and scope of the invention.

1. An edge seal for manufacturing two-pane or multi-pane insulating glass or solar modules, the edge seal including a sealant and a bonding agent, wherein the sealant contains a polymer modified with special reactive groups and has the following overall composition:
a) unsaturated or reactive polyolefins or combinations thereof in an amount from about 10% to 80% by weight of the total composition;
b) olefinic polymers or combinations thereof included in an amount from about 5% to about 80% by weight of the total composition;
c) at least one filler included in an amount from about 10% to about 60% by weight of the total composition;
d) at least one of a desiccant or water scavenger included in an amount from about 2.5% to about 25% by weight of the total composition; and
e) at least one aging resistor including an anti-oxidant or UV stabilizer included in an amount from about 0.1% to about 3% by weight of the total composition.

2. The edge seal of claim 1, wherein the olefinic polymers are included in an amount from about 5% to about 50% by weight of the total composition and a silane modified polymer is included in an amount from about 5% to about 30% by weight of the total composition.

3. The edge seal of claim 2 wherein the fillers further include fine particle fillers in an amount from about 5% to about 50% by weight of the total composition.

4. The edge seal of claim 2 wherein the olefinic polymers are selected from the group consisting of polyisobutylene, polybutene, butyl rubber (polyisobutylene-isoprene), styrene block copolymers, SBS (styrene-butadiene- styrene), SIS (styrene-isoprene-styrene), SEBS (styrene-ethylene-butylene-styrene), SEPS (styrene-ethylene-propylene-styrene), SIBS (styrene-isoprene-butadiene-styrene), SPIBS (styrene-polyisobutylene-styrene), also in modified form, and amorphous copolymers and/or terpolymers of α-olefins (APAO).

5. The edge seal of claim 2 wherein the silane modified polymer is selected from the group consisting of polyisobutylene, polybutene, butyl rubber (polyisobutylene-isoprene), styrene block copolymers, SBS (styrene-butadiene-styrene), SIS (styrene-isoprene-styrene), SEBS (styrene-ethylene-butylene-styrene), SEPS (styrene-ethylene-propylene-styrene), SIBS (styrene-isoprene-butadiene-styrene), SPIBS (styrene-polyisobutylene-styrene), and amorphous copolymers and/or terpolymers of α-olefins (APAO).

6. The edge seal of claim 5 wherein the APAO polymers are modified with at least one group of formula (1) which is a terminal group or is distributed statistically within the chain 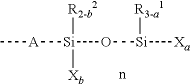
where -A- is 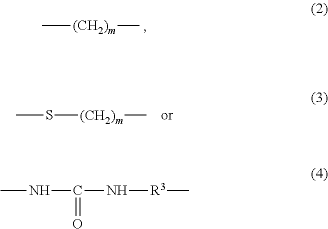
and R¹ and R² are the same or different and are an alkyl group having 1 to 20 carbon atoms, an aryl group having 6 to 20 carbon atoms or an aralkyl group having 7 to 20 carbon atoms,
X is a hydroxyl group or a hydrolyzable group,
a is 0, 1, 2 or 3 and b is 0, 1 or 2, the sum of a and b being greater than or equal to 1, and where n is a whole number between 0 and 18, m is a whole number between 0 and 4 and R³ is

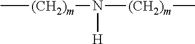

7. The edge seal of claim 3 wherein the fine particle fillers of the sealant are selected from the group comprising ground and precipitated chalks, silicates, lime, silicon oxides and Carbon blacks.

8. The edge seal of claim 7 wherein the chalks of the sealant are surface-treated calcium carbonate.

9. The edge seal of claim 7 wherein the silicates of the sealant are selected from the group consisting of talc, kaolin, mica, silicon oxides, silicas and calcium or magnesium silicates.

10. The edge seal of claim 1 wherein the desiccants or water scavengers of the sealant are selected from the group consisting of molecular sieves, phosphorous pentoxide, calcium oxide, anhydrous salt, epoxidized vegetable oil, carbodiimide, p-toluenesulfonyl isocyanate or combinations thereof.

11. The edge seal of claim 1 wherein the desiccants or water scavengers of the sealant are selected from molecular sieves (zeolites) of types 3A to 10A.

12. The edge seal of claim 1 wherein the aging resistors of the sealant are selected from the group comprising sterically hindered phenols, thioethers, mercapto compounds, phosphorus esters, benzotriazoles, benzophenones, HALS (Hindered Amine Light Stabilizers) and antioxidants.

13. The edge seal of claim 1 wherein the unsaturated or reactive polyolefins are selected from the group EPDMs, polyolefin acrylates, and halobutyls

14. The edge seal of claim 2 wherein the olefinic polymers are included in an amount from about 30% to about 50% by weight and have an Mn from about 5,000 D to about 1,000,000 D, the silane modified polymer is included in an amount from about 5% to about 25% by weight, and the desiccants or water scavengers are included in an amount up to about 15% by weight of the total composition.

15. A solar module comprising:
a first substrate;
a second substrate;
at least one photovoltaic cell disposed between the first and second substrates;
a sealant in contact with the first and second substrates to form a moisture vapor barrier to hinder moisture vapor from reaching the at least one photovoltaic cell, wherein the sealant includes:
an unsaturated or reactive polyolefin
an olefinic polymer;
at least one of a silane modified APAO and a silane modified polyisobutylene;
at least one filler;
at least one of a water scavenger or a desiccant; and
at least one aging resistor, and
wherein the sealant electrically insulates the photovoltaic cell.

16. The solar module of claim 15 wherein at least one of the first and second substrates is at least one of glass, polymeric and metallic.

17. The solar module of claim 15 wherein the unsaturated or reactive polyolefin is included in the amount from about 10% to about 80% by weight of the total composition, the olefinic polymer includes a polyisobutylene in an amount from about 5% to about 50% by weight of the total composition, the at least one of the silane modified APAO and the silane modified polyisobutylene is included in an amount from about 5% to about 30% by weight of the total composition, the filler is included in an amount from about 10% to about 60% by weight of the total composition, the at least one of the water scavenger or the desiccant is included in an amount from about 2.5% to about 25% by weight of the total composition, and the aging resistor is included in an amount from 0.1% to about 3% by weight of the total composition.

18. A compound used in a solar module having a photovoltaic cell, the compound comprising:
an unsaturated or reactive polyolefin;
an olefinic polymer;
at least one of a silane modified APAO and a silane modified polyisobutylene;
at least one filler;
at least one of a water scavenger or a desiccant; and
at least one aging resistor, and
wherein the compound electrically insulates the photovoltaic cell.

19. The compound of claim 18 wherein the unsaturated or reactive polyolefin is included in the amount from about 10% to about 80% by weight of the total composition, the olefinic polymer includes a polyisobutylene in an amount from about 5% to about 50% by weight of the total composition, the at least one of the silane modified APAO and the silane modified polyisobutylene is included in an amount from about 5% to about 30% by weight of the total composition, the filler is included in an amount from about 10% to about 60% by weight of the total composition, the at least one of the water scavenger or the desiccant is included in an amount from about 2.5% to about 25% by weight of the total composition, and the aging resistor is included in an amount from 0.1% to about 3% by weight of the total composition.

20. A sealing compound for use in a solar module having a first substrate and a second substrate, wherein the sealing compound is disposed between the first substrate and the second substrate, the sealing compound comprising:
an unstaturated or reactive polyolefin;
an olefinic polymer in an amount greater than about 30% by weight of the total composition;
at least one of a silane modified APAO and a silane modified polymer in an amount less than 35% by weight of the total composition;
a filler;
a carbon black having a primary particle size of less than about 60 nm;
at least one of a water scavenger or a desiccant; and
an aging resistor.
